(19) United States
(12) Patent Application Publication
(10) Pub. No.: US 2002/0070394 A1
(43) Pub. Date: Jun. 13, 2002

(54) Using segmented N-type channel stop to enhance the SOA (safe-operating area) of LDMOS transistors

(76) Inventors: John Lin, Chelmsford, MA (US); Philip L. Hower, Concord, MA (US)

Correspondence Address: TEXAS INSTRUMENTS INCORPORATED, P O BOX 655474, M/S 3999, DALLAS, TX, 75265

(21) Appl. No.: 09/732,859

(22) Filed: Dec. 8, 2000

(51) Int. Cl. H01L 29/80; H01L 31/112

(52) U.S. Cl. 257/262

(57) ABSTRACT

A semiconductor device includes a gate to control the semiconductor device, a drain coupled to the gate, a source to form a current path with the drain, a field oxide coupled to the gate, and a channel stop formed under the field oxide.

### FIELD OF THE INVENTION

The present invention relates to power semiconductor devices and more particularly to power lateral DMOS.

### BACKGROUND OF THE INVENTION

For many power integrated circuit applications, the lateral DMOS provides a nearly ideal output device. The lateral DMOS is easy to drive and makes an efficient switch. Additionally, the lateral DMOS is favorable to be adapted to successive generations of CMOS processes technology, and consequently it has resulted in the wide use of the Ldmos as an output driver.

A large number of commercial applications for IC output drivers require blocking voltages in the range of 20-60 volts, and a current capability in the 1-3 amp range.

The safe operating area (SOA) of the device is a measure of the device's ability to turn off current in an inductive load or a capacitive load. The boundaries of the safe operating area are limited by a combination of a voltage applied across the device and the current flowing through the device and depends on device structure and characteristics. The larger the SOA of a device is; the larger the inductive current is that the device can turn off without damage to the device. When the device turns off while controlling an inductive load, the voltage across the device increases substantially while the inductive load prevents the current from decreasing to zero immediately. Likewise for a device controlling a capacitive load, the current through the device increases substantially while a capacitor flow prevents the voltage from decreasing to zero immediately. The safe operating area of the device is substantially effected by the mobile charge carrier density within the device during turnoff because the presence of mobile charge characters results in an increase in internal electric fields within the device structure. The SOA can be defined in a region within the I-V plane where the Ldmos operating point has normal gate control. When the operating point goes outside the SOA, gate control is lost, and device destruction usually takes place. At low drain voltages, the operating point of the Ldmos device is limited by the maximum field on the gate oxide for example, 4×10⁶V/cm or by an elecromigration current density limit for example, 5×10⁵A/cm2, in chip metallization.

The SOA boundary that results in device destruction is determined by the onset of negative resistance.

From a mathematical standpoint, the SOA boundary defines a location of singularities in equations which describe the I-V behavior of the Ldmos. For V_{GS} which is held constant, the output conductance defined by dl_{D}/dV_{DS} is positive within the boundary becomes infinite at the boundary and negative outside the boundary. The similarity with V_{DS} being held constant, the transconductance defined by dl_{D}/dV_{GS} becomes infinite at the boundary and changes sign as the operating point crosses the boundary. Because device destruction occurs at the boundary, designers are typically interested in ways of shifting the SOA boundary to a higher current or a higher voltage region, preferably without compromising the desirable features of the Ldmos. Therefore, to determine the boundary location of the SOA as a function of a structure and process steps is one of the primary goals of Ldmos analysis and design.

The SOA boundary becomes especially important during switching events as described as the turn on of a charge capacitor and a turnoff of a charge inductor. For capacitive turn on, the device failure occurs as the current increases from zero at constant V_{DS} and intersects the SOA boundary. For inductive turnoffs, V_{DS} is typically limited by using a “active clamp” where gate-drain voltage is limited by an on chip or external voltage clamp.

FIG. 1 illustrates an Ldmos device. In FIG. 1, a P body 108 is located in N well 114. Additionally, a back gate 110 is formed by P body 108. A source 112 is formed in P body 108. A gate 106 extends from the source 112 to approximately half way across the field oxide or FOX 104. A channel stop 102 is formed underneath the field oxide 104 to point B. The drain abuts the field oxide 104.

FIG. 2 illustrates the doping levels associated with the N well and channel stop as well as the electron concentration under high current injection. Starting at point A, the doping level 202 increases and remains relatively constant until point B where again the doping level 202 increases. Likewise, the electron concentration 204 is increasing at point A and reaches an approximate level electron concentration 204 at point B and again sharply increases at point B.

FIG. 3 illustrates the electric field across the Ldmos device. The electric field 302 increases rapidly and reaches a peak at approximately point A and then decreases to substantially level at point E and increases dramatically as point B is approached. As can be illustrated in FIG. 3, the electric field is reduced for the most part between points A and B. This leads to a SOA boundary that is unsatisfactory.

### SUMMARY OF THE INVENTION

The present invention provides a structure that increases the SOA by providing a segmented N-channel stop. Breaks in the N-channel stop increases the electric field.

### BRIEF DESCRIPTION OF THE DRAWINGS

FIG. 1 illustrates a lateral DMOS;

FIG. 2 illustrates the doping level and electron concentration corresponding to the device of FIG. 1;

FIG. 3 illustrates a diagram of electric field corresponding to the device of FIG. 1;

FIG. 4 illustrates a lateral DMOS device of the present invention;

FIG. 5 illustrates an electron concentration and doping level of the device of FIG. 4;

FIG. 6 illustrates a diagram of electric field of the device of FIG. 4;

FIG. 7a-d illustrates a diagram of a process of the present invention; and

FIG. 8 illustrates alternative process steps of the present invention.

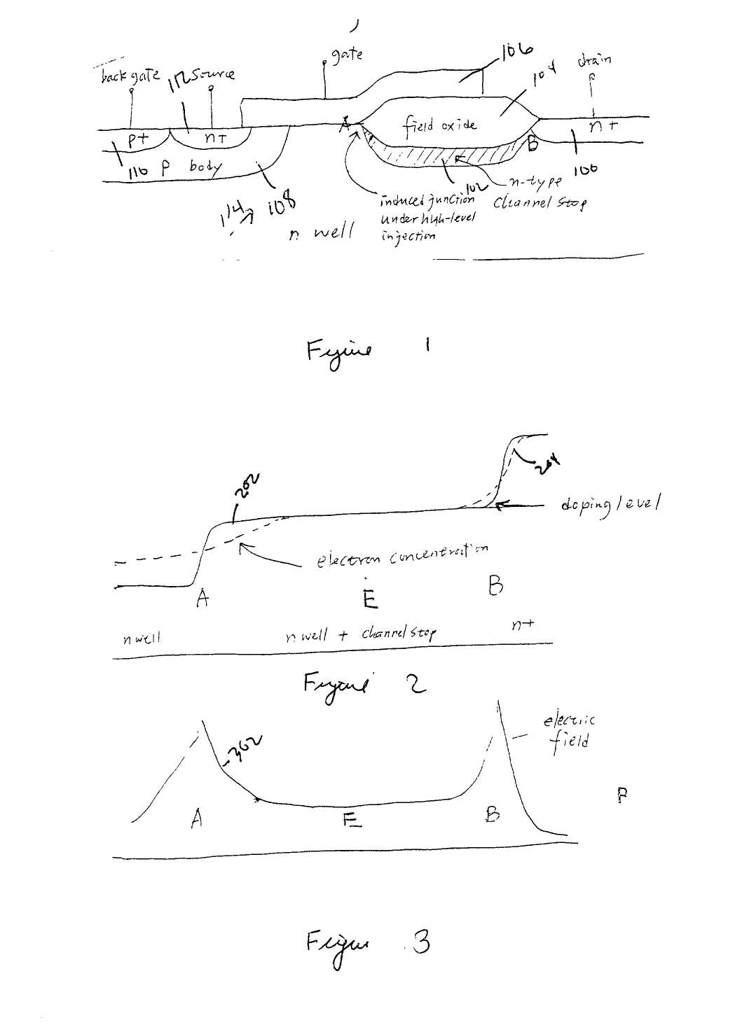

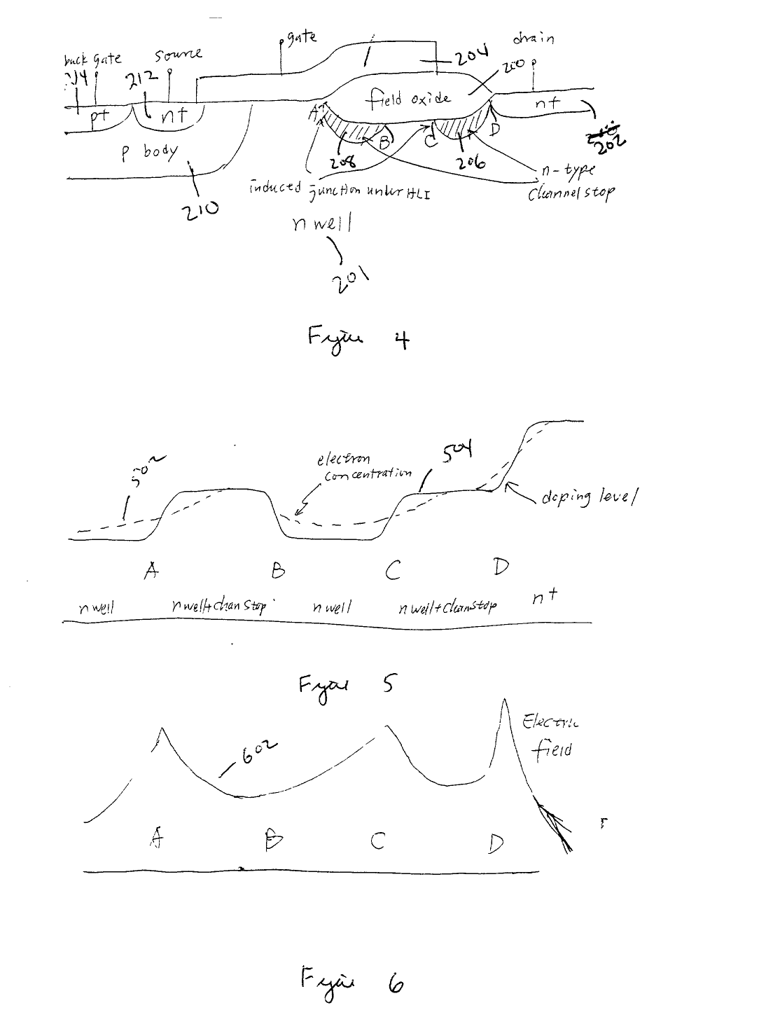

### DETAILED DESCRIPTION OF THE PRESENT INVENTION

The Ldmos device of the present invention is illustrated in FIG. 4. Such a device results in improving the safe operating area such that the operating point of the Ldmos device or any device has an operating point that takes a path such that during a transition from a high current to a low voltage or from a low current to a high voltage. If the SOA boundary is not crossed, and consequently destruction of the device will not occur.

In FIG. 4, a field oxide 200 is formed such that high electric fields can form between the drain 202 and the source 212. The high electric fields generate additional carriers which cause the negative resistance which results in the destruction of the device during transitions by crossing the SOA. The channel stop regions 206 and 208 as illustrated in FIG. 4 effectively moves the SOA outwards giving a greater area of operation for the Ldmos device The spacing between point A and point B is illustrated in FIG. 4 as relatively small and on the order of a few microns, and this size requires that only two regions be present. However, for improved results additional areas of channel stop regions could be introduced especially where the spacing between point A and point B is larger. N-type channel devices have more of a need for the channel stops than p-type channel devices. However such a device as described herein would work equally well for p channel devices.

Additionally, as illustrated in FIG. 4, the N well 201 has formed a P body 210 in which a source of N+ material is formed and in which a back gate 214 is formed of P+ material. Additionally, extending from the source 212 a gate 204 is formed over the N well 201 to cover approximately one-half the field oxide 200. Adjacent to the field oxide 200 is a N+ region 202 or drain 202. Substantially under the field oxide 200 are two n channel stops namely n type channel stop 208 and n type channel stop 206. Points A, B, C and D illustrate the points where n type channel stops 206 and 208 begin and end. Point A is the start of n channel 208 and point B is the end of n stop channel 208. Point C is the start of n channel 206 and point D is the end of n stop channel 206.

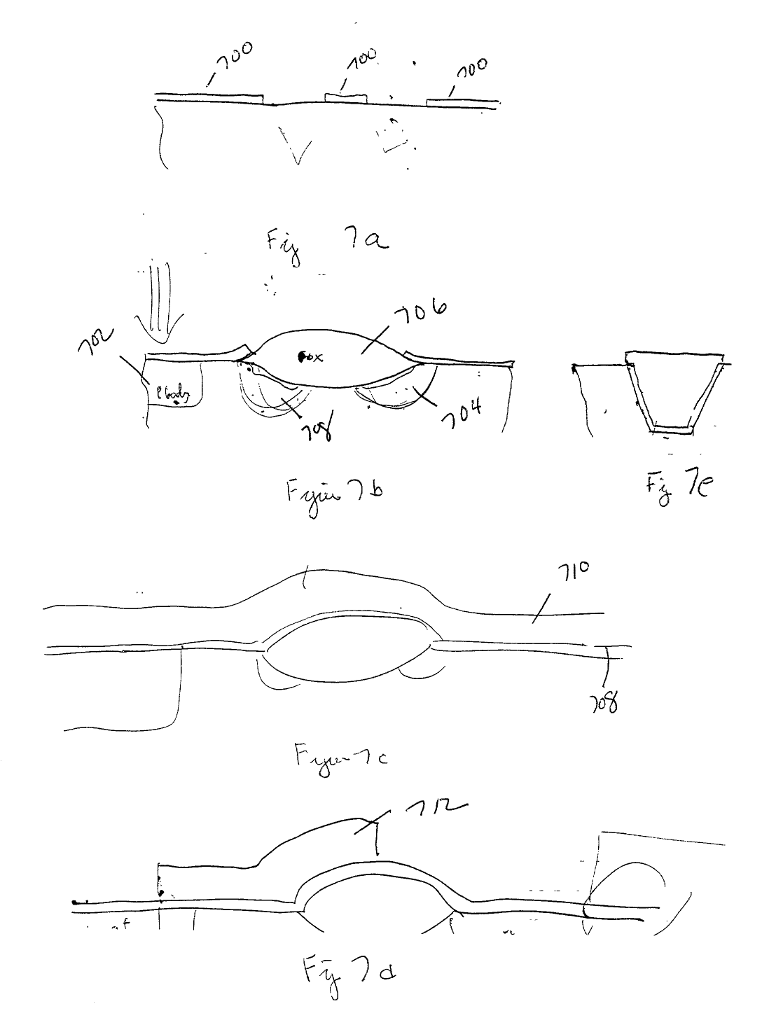

Turning now to FIG. 5, FIG. 5 illustrates the electron concentration under high current injection along a curve 502 and the doping level along curve 504. At point A the doping level illustrated by curve 504 increases until point B is reached at which time it decreases. At point C, the curve 504 indicating doping level increases and at point D the doping level again increases indicating the effects of the drain 200.

Turning now to FIG. 6, at point A, the electric field under high current injection illustrated by curve 602 increases dramatically to a peak at point A and decreases to point B and again reaches another peak at point C and decreasing between point C and point D and the electric field increases to another peak at point D.

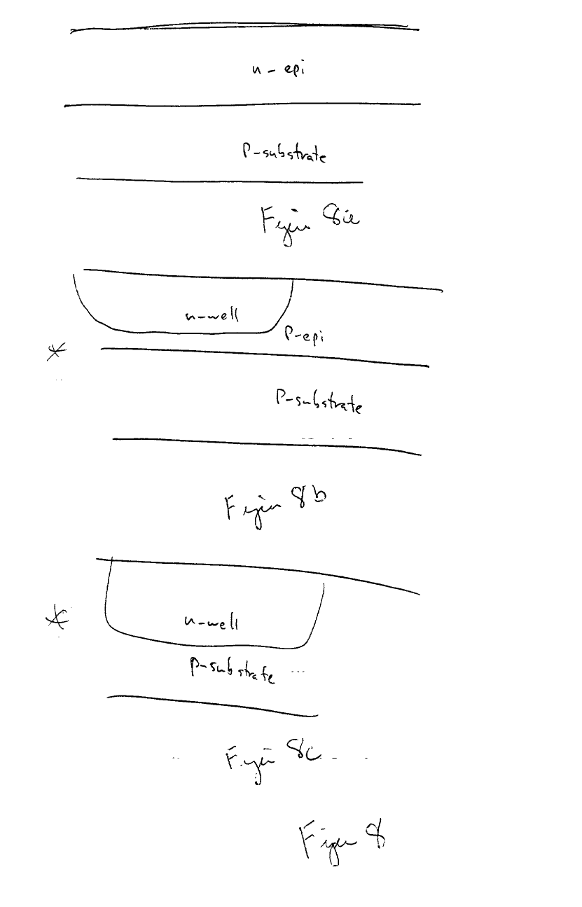

The process to form the device is illustrated in FIG. 7. In FIG. 7a, a mask 700 is placed on n-type epi material. The mask 700 may be a silicon nitride Si₃N₄ or photoresist or SiO₄. Doping is achieved by implanting. Next, the device is subject to an oxidizing ambient for example, O₂or H₂O at 900 degrees-1200 degrees Kelvin at which point the field oxide 706 is grown and the P body 702 and n channel stops 704 and 706 are driven. FIG. 7e shows an alternative method of growing the field oxide in a shallow trench by oxidizing an undoped polysilicon and a silicon nitride and/or thermally grown oxide along the edges of the shallow trench. Next, implant is used with boron after the thermal oxidation.

Turning now to FIG. 7c, the device is covered with a gate insulator. A silicon oxide SiO₂ or silicon oxide/nitride stack is used to form the gate insulator 708. Next, an additional layer 710 is deposited which may be a polysilicon which is intrinsically doped or a metal overlay device. Next, as illustrated in FIG. 7d, the gate 712 is formed by using a pattern and etching.

FIG. 8 illustrates alternatives for forming the substrate. In FIG. 8a, an epi layer is formed over a p substrate layer. FIG. 8b illustrates a p substrate under a p epi layer that includes a n-well. FIG. 8c illustrates an n-well within a p substrate.

1. A semiconductor device, comprising:
a gate to control said semiconductor device;
a drain coupled to said gate;
a source to form a current path with said drain;
a field oxide area coupled to said gate; and
a channel stop under said field oxide area.

2. A semiconductor device as in claim 1, wherein said channel stop is a n-type channel stop.

3. A semiconductor device as in claim 1, wherein said source is n-type material.

4. A semiconductor device as in claim 1, wherein said drain is n-type material.

5. A semiconductor device as in claim 1, wherein said channel stop includes a first channel stop and a second channel stop, said first channel stop not being directly connected to said second channel stop.

6. A semiconductor device as in claim 5, wherein said first channel stop is a n-type channel stop.

7. A semiconductor device as in claim 6, wherein said second channel stop is a n-type channel stop.

8. A semiconductor device as in claim 9 wherein said semiconductor device includes a back gate.
